(19) United States
(12) Patent Application Publication
(10) Pub. No.: US 2007/0102773 A1
(43) Pub. Date: May 10, 2007

(54) SEMICONDUCTOR DEVICE AND METHOD OF MANUFACTURING SAME

(75) Inventors: Kiyoshi HISATOMI, Kanagawa-ken (JP); Yasuhisa Ohmuro, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ko (JP)

(21) Appl. No.: 11/555,385

(22) Filed: Nov. 1, 2006

(30) Foreign Application Priority Data
Nov. 9, 2005 (JP) 2005-324850

(51) Int. Cl. H01L 29/76

(52) U.S. Cl. 257/401; 257/368

(57) ABSTRACT

A semiconductor device includes: a semiconductor layer of a first conductivity type; a first semiconductor pillar region of the first conductivity type provided on a major surface of the semiconductor layer; a second semiconductor pillar region of a second conductivity type provided on the major surface of the semiconductor layer, the second semiconductor pillar region being adjacent to the first semiconductor pillar region; and a dielectric filled inside a trench, the trench being provided adjacent to the first semiconductor pillar region and away from the second semiconductor pillar region. The first semiconductor pillar region, the second semiconductor pillar region, and the trench are extending along a first direction. The first direction is substantially perpendicular to the depth direction of the trench. At least both ends of the first semiconductor pillar region in the first direction are provided more inside than both ends of the trench in the first direction.

### CROSS-REFERENCE TO RELATED APPLICATION

This application is based upon and claims the benefit of priority from the prior Japanese Patent Application No. 2005-324850, filed on Nov. 9, 2005; the entire contents of which are incorporated herein by reference.

### BACKGROUND OF THE INVENTION

1. Field of the Invention

This invention relates to a semiconductor device and a method of manufacturing the same, and more particularly to a semiconductor device having a super junction structure and a method of manufacturing the same.

2. Background Art

Conventionally, as a semiconductor device suitable for power electronics applications, semiconductor devices having a “super junction structure” have been known. The super junction structure is such that n-type pillar regions and p-type pillar regions are alternately arranged on a semiconductor substrate. For example, in a proposed technique (e.g., JP 2002-170955A), n-type and p-type impurities are injected by ion implantation into the side face of the trenches provided in an epitaxial layer on the semiconductor substrate, and then diffused into the epitaxial layer to form n-type pillar regions and p-type pillar regions.

However, in such semiconductor devices, crystal defects such as slip dislocations are likely to occur at the trench end under the influence of stress during thermal oxidation of the trench inner wall or oxidation for burying a filling, as well as stress due to the filling.

### SUMMARY OF THE INVENTION

According to an aspect of the invention, there is provided a semiconductor device including: a semiconductor layer of a first conductivity type; a first semiconductor pillar region of the first conductivity type provided on a major surface of the semiconductor layer; a second semiconductor pillar region of a second conductivity type provided on the major surface of the semiconductor layer, the second semiconductor pillar region being adjacent to the first semiconductor pillar region; and a dielectric filled inside a trench, the trench being provided adjacent to the first semiconductor pillar region and away from the second semiconductor pillar region, wherein the first semiconductor pillar region, the second semiconductor pillar region, and the trench are extending along a first direction, the first direction is substantially perpendicular to the depth direction of the trench, and at least both ends of the first semiconductor pillar region in the first direction are provided more inside than both ends of the trench in the first direction.

According to other aspect of the invention, there is provided a semiconductor device including: a semiconductor layer of a first conductivity type; a first semiconductor pillar region of the first conductivity type provided on a major surface of the semiconductor layer; and a second semiconductor pillar region of a second conductivity type filled inside a trench, the trench being provided adjacent to the first semiconductor pillar region, wherein the first semiconductor pillar region and the trench are extending along a first direction, the first direction is substantially perpendicular to the depth direction of the trench, and both ends of the first semiconductor pillar region in the first direction are provided more inside than both ends of the trench in the first direction.

According to other aspect of the invention, there is provided a method of manufacturing a semiconductor device, including: forming a trench in a second semiconductor layer formed on a major surface of a first semiconductor layer of a first conductivity type; injecting impurities of the first conductivity type into a sidewall of the trench while both ends of the trench are covered with a mask; forming a first semiconductor pillar region of the first conductivity type adjacent to the trench by diffusing the impurities of the first conductivity type; and forming a second semiconductor pillar region of the second conductivity type adjacent to the first semiconductor pillar region.

### BRIEF DESCRIPTION OF THE DRAWINGS

FIG. 1 is a schematic view illustrating the planar structure of the relevant part of a semiconductor device according to a first embodiment of the invention.

FIG. 2 is a schematic view illustrating the cross-sectional structure along the line A-A in FIG. 1 of the relevant part of the semiconductor device according to the first embodiment.

FIG. 3 is a schematic view illustrating the planar structure of the relevant part of a semiconductor device of a comparative example.

FIG. 4 is an electron micrograph in the vicinity of a corner at the bottom of the trench end.

FIG. 5 is a voltage-current characteristic diagram of a semiconductor device according to the first embodiment of the invention.

FIG. 6 is a voltage-current characteristic diagram of a semiconductor device of the comparative example.

FIGS. 7 is a process cross section along the line A-A in FIG. 1 illustrating the relevant part of a process of manufacturing a semiconductor device according to the first embodiment of the invention.

FIG. 8 is a process cross section subsequent to FIG. 7.

FIG. 9 is a plan view of FIG. 8.

FIG. 10 is a plan view illustrating the step subsequent to FIG. 9.

FIGS. 11 to 14 are process cross sections subsequent to FIG. 10.

FIG. 15 is a schematic view illustrating the planar structure of the cell of a semiconductor device according to a second embodiment of the invention.

FIG. 16 is a schematic view illustrating the cross-sectional structure along the line B-B in FIG. 15 of the cell of the semiconductor device according to the second embodiment.

FIG. 17 is a plan view illustrating the relevant part of a process of manufacturing a semiconductor device according to the second embodiment.

FIG. 18 is a plan view illustrating the step subsequent to FIG. 17.

FIG. 19 is a plan view illustrating the step subsequent to FIG. 18.

FIGS. 20 to 22 are process cross sections subsequent to FIG. 19.

FIG. 23 is an electron micrograph of the cross section in relation to FIG. 22.

FIG. 24 is a process cross section subsequent to FIG. 22.

FIG. 25 is a schematic view illustrating the cross-sectional structure of the relevant part of a semiconductor device according to a third embodiment of the invention.

FIG. 26 is a schematic view illustrating the planar structure of the termination of a semiconductor device according to a second embodiment of the invention.

FIG. 27 is a schematic view illustrating the cross-sectional structure of the termination of the semiconductor device according to the second embodiment.

FIG. 28 is a schematic view illustrating the variation of the configuration of the trench end.

### DETAILED DESCRIPTION OF THE INVENTION

Embodiments of the invention will now be described with reference to the drawings. While the following embodiments are described assuming the first conductivity type as N-type and the second conductivity type as P-type, the invention also encompasses embodiments that assume the first conductivity type as P-type and the second conductivity type as N-type.

First Embodiment

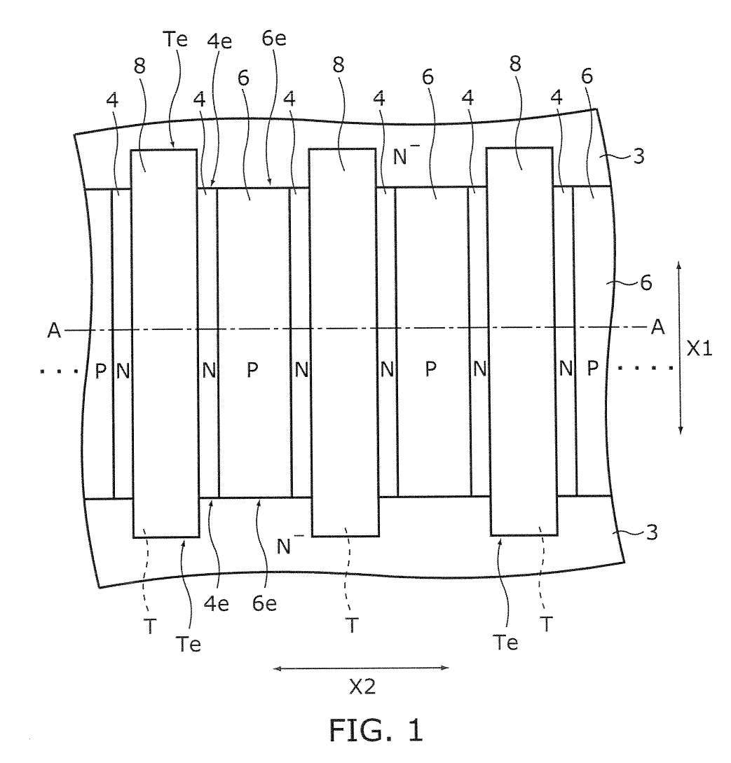

FIG. 1 is a schematic view illustrating the planar structure of the relevant part of a semiconductor device according to a first embodiment of the invention.

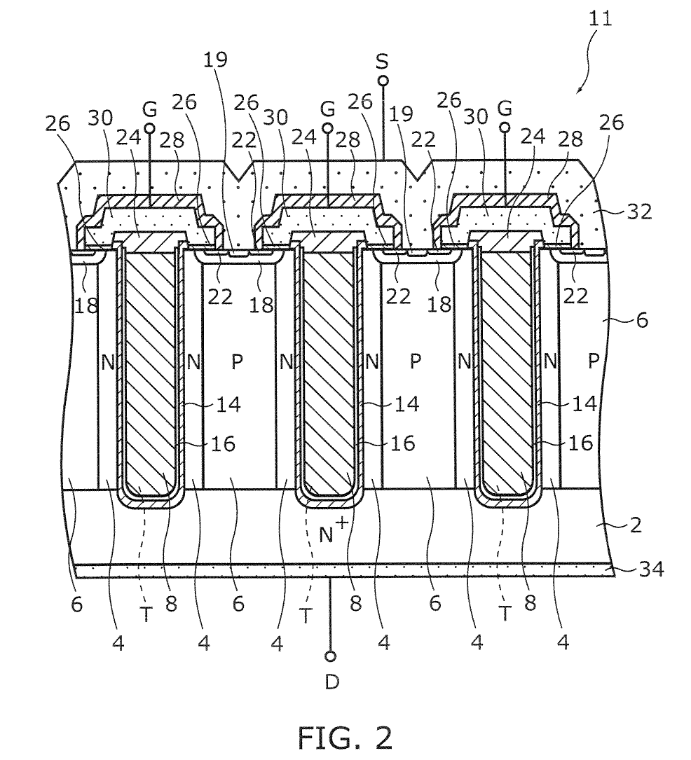

FIG. 2 is a schematic view illustrating the cross-sectional structure along the line A-A in FIG. 1 of the relevant part of the semiconductor device.

In the semiconductor device 11 according to this embodiment, on a major surface of an N⁺-type silicon substrate (first semiconductor layer) 2 having a high impurity concentration, first pillar regions 4 of N-type silicon (hereinafter also simply referred to as “N-type pillar regions”) and second pillar regions 6 of P-type silicon (hereinafter also simply referred to as “P-type pillar regions”) are provided in parallel.

A trench T is adjacent to the surface of the N-type pillar region 4 on the opposite side of the surface adjacent to the P-type pillar region 6. The inside of the trench T is filled with a dielectric 8 made of silica, for example, via a silicon oxide film 14 and a silicon nitride film 16. The trench T and the dielectric 8 are sandwiched between the N-type pillar regions 4. Note that the dielectric 8 is not limited to silica, but may be other dielectrics such as silicon nitride (example of nitride), oxide.

As shown in the cross-sectional structure of FIG. 2, the trench T, the dielectric 8, the N-type pillar region 4, and the P-type pillar region 6 extend substantially perpendicular to the major surface of the substrate 2. The N-type pillar regions 4 are adjacent to both sides of the P-type pillar region 6 to form a PN junction.

FIG. 1 shows the planar structure of the trench T, the dielectric 8, the N-type pillar region 4, and the P-type pillar region 6. The trench T, the dielectric 8, the N-type pillar region 4, and the P-type pillar region 6 extend along a first direction X1. The first direction X1 is a direction substantially perpendicular to the depth direction of the trench T and corresponds to the direction going through the page in the cross section of FIG. 2.

On the plane shown in FIG. 1, the combination of a trench T, an N-type pillar region 4, and a P-type pillar region 6 is repeated along a second direction X2 that is substantially perpendicular to the first direction X1. For example, a trench X, an N-type pillar region 4 adjacent thereto, a P-type pillar region 6 adjacent thereto, and an N-type pillar region 4 adjacent thereto can be considered as one unit. Then, 250 units per chip are repeated in the second direction X2. For example, the trench T, the N-type pillar region 4, and the P-type pillar region 6 have a length of 7, 5, and 10 micrometers, respectively, along the second direction X2.

The N-type pillar region 4 and the P-type pillar region 6 have a substantially equal length along the first direction X1. The length of the N-type pillar region 4 and the P-type pillar region 6 along the first direction X1 is shorter than length of the trench T along the first direction X1. Both ends of the N-type pillar region 4 and the P-type pillar region 6 in the first direction X1 are located more inside than both ends of the trench T in the first direction X1. For example, the trench T has a length of 2.5 to 4 millimeters along the first direction X1. Both ends 4e, 6e of the N-type pillar region 4 and the P-type pillar region 6, respectively, are located more inside than both ends Te of the trench T by about 10 to 50 micrometers, for example. Conversely, both ends Te of the trench T protrude from both ends 4e, 6e of the N-type pillar region 4 and the P-type pillar region 6 by about 10 to 50 micrometers.

An active region (base region 18, source region 22) described below is formed on the P-type pillar region 6. The active region does not extend to both ends Te of the trench T. Preferably, the ends of the active region in the first direction X1 slightly extend out from the ends 6e of the P-type pillar region 6.

Referring again to FIG. 2, a base region 18 of P-type silicon is provided on the P-type pillar region 6. Furthermore, a base contact region 19 of P⁺-type silicon having a higher impurity concentration than the base region 18 is provided on the surface of the base region 18. Moreover, a semiconductor region (source region) 22 of N⁺-type silicon is provided on the surface of the base region 18 so as to sandwich the base contact region 19. The base region 18 is adjacent to the N-type pillar region 4 to form a PN junction.

An insulating film 26 is provided on the surface of the portion extending from the N-type pillar region 4 via the base region 18 to the source region 22. This insulating film 26 is gate insulating film. An insulating film 24 is provided also on the dielectric 8. A control electrode (gate electrode) 30 is provided on the insulating films 24, 26. The periphery and the upper surface of the control electrode 30 are covered with an interlayer insulating film 28. A first main electrode (source electrode) 32 is provided on the portion of the source region 22 not covered with the interlayer insulating film 28, on the base region 19, and on the interlayer insulating film 28. The source region 22 is connected to the first main electrode 32. The base region 18 is connected to the first main electrode 32 via the base contact region 19. A second main electrode (drain electrode) 34 is provided on the surface opposite to the major surface of the substrate 2.

In the semiconductor device 11 configured as above, a prescribed control voltage is applied to the control electrode 30. Then an N-channel is formed in the vicinity of the surface of the P-type base region 18 immediately below the control electrode 30, and the N⁺-type source region 22 becomes conductive to the N-type pillar region 4. As a result, a main current path is formed between the first main electrode 32 and the second main electrode 34 via the N⁺-type source region 22, the N-type pillar region 4, and the N⁺-type substrate 2. Thus the path between these electrodes 32, 34 is turned on.

The device withstand voltage can be maintained by the depletion layer laterally extending from the PN junction between the N-type pillar region 4 and the P-type base region 18 and from the PN junction between the N-type pillar region 4 and the P-type pillar region 6, and by the dielectric 8 buried in the trench T.

In the semiconductor device 11 according to this embodiment, as described above with reference to FIG. 1, the N-type pillar region 4 and the P-type pillar region 6 are not formed in the vicinity of the ends Te of the trench T (about 10 to 50 micrometers inside from the end of the trench T). That is, the main current path including the channel is not formed in the vicinity of the ends Te of the trench T.

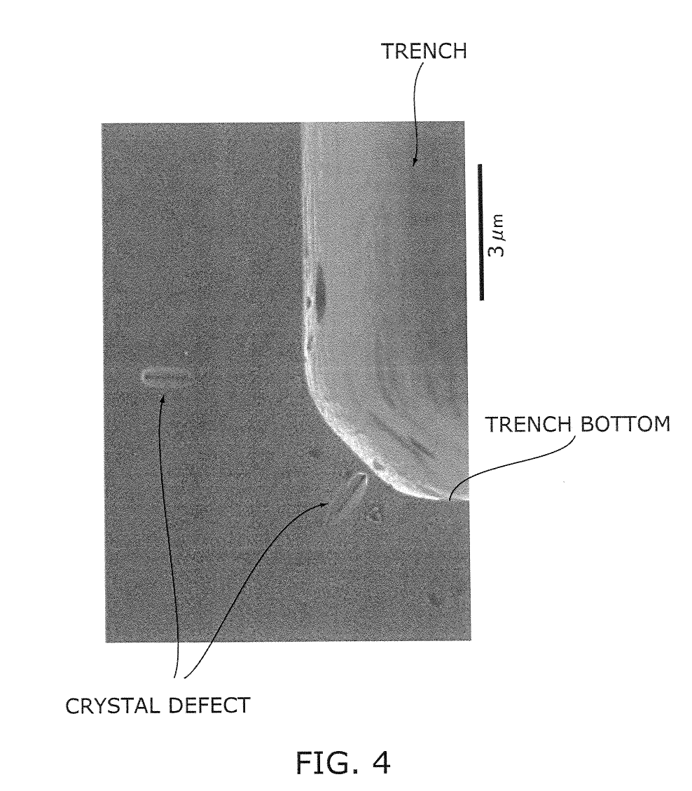

FIG. 4 is an electron micrograph in the vicinity of a corner at the bottom of the trench end where a silicon oxide film is formed on the inner wall of the trench (with no filling). As shown in FIG. 4, in general, crystal defects such as slip dislocations are likely to occur at the trench end under the influence of stress during thermal oxidation of the trench inner wall or oxidation for burying silica or the like, as well as stress due to the filling.

In contrast, as described above, this embodiment has a structure such that the vicinity of the trench end, where crystal defects are likely to occur, is not used as an operating region of the device. Therefore, even if any crystal defects occur in the vicinity of the trench end, they do not affect the product quality. This results in products with high yield and good quality.

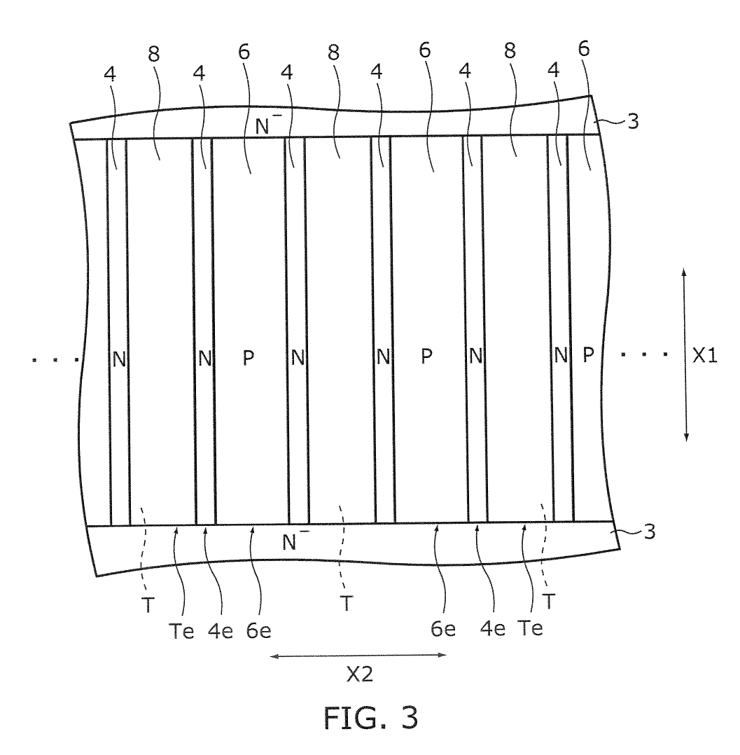

FIG. 3 shows a comparative example where the N-type pillar region 4 and the P-type pillar region 6 are formed to reach both ends of the trench T. Semiconductor devices of this structure exhibited a yield of 30%, and withstand voltage failure accounts for 90% of the defectives.

FIG. 6 shows the voltage-current characteristics of a semiconductor device of the comparative example. A scale division on the horizontal axis corresponds to 100 volts, and a scale division on the vertical axis corresponds to 200 microamperes. As shown, the current begins to flow before a desired voltage is reached at which the current is intended to begin flowing. Upon investigation of current leak spots, trench ends account for 85%.

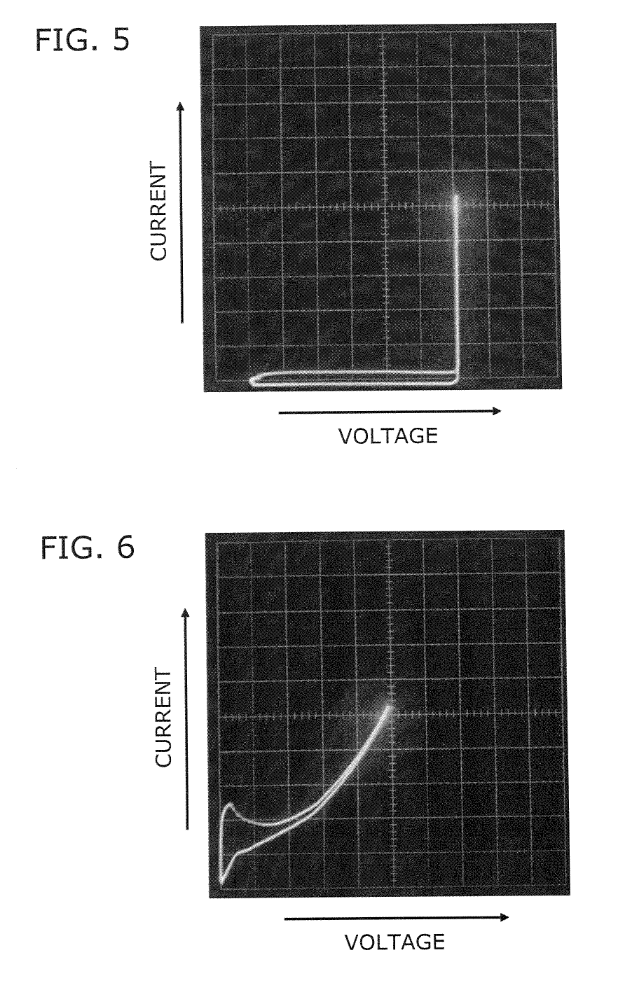

In contrast, in the semiconductor device 11 according to this embodiment, as shown in FIG. 5, the current does not flow until a desired voltage (e.g., 600 volts) is reached, and thus a desired withstand voltage is ensured. In FIG. 5 again, a scale division on the horizontal axis corresponds to 100 volts, and a scale division on the vertical axis corresponds to 200 microamperes. By using the structure of the semiconductor device 11 according to this embodiment, the yield is increased to 90%, and the occupation rate of withstand voltage failure is drastically decreased to 4%. Thus the cost can be reduced.

Next, an example method of manufacturing a semiconductor device according to this embodiment is described.

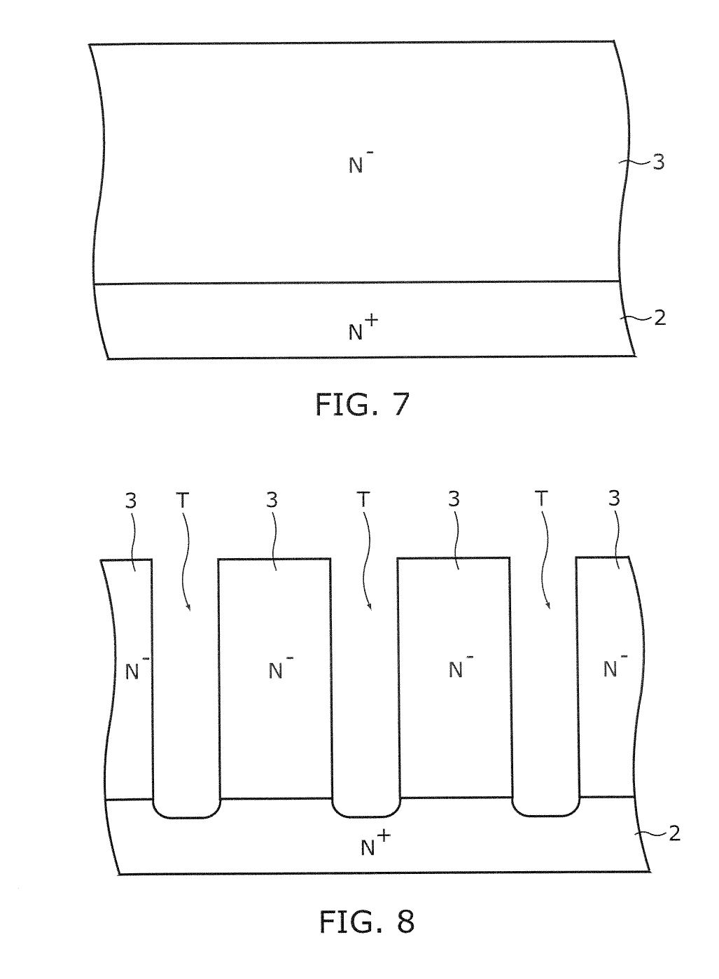

FIGS. 7 to 14 are process cross sections illustrating the relevant part of a process of manufacturing a semiconductor device according to this embodiment.

First, as shown in FIG. 7, on a major surface of an N⁺-type silicon substrate (first semiconductor layer) 2 having a high impurity concentration, an N⁻-type silicon layer (second semiconductor layer) 3 having a low impurity concentration is epitaxially grown. Note that the second semiconductor layer 3 may be of P⁻-type.

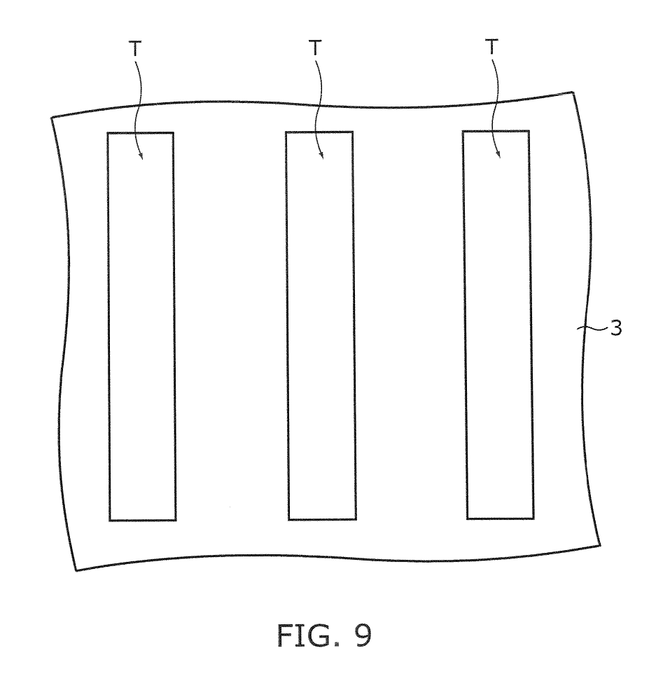

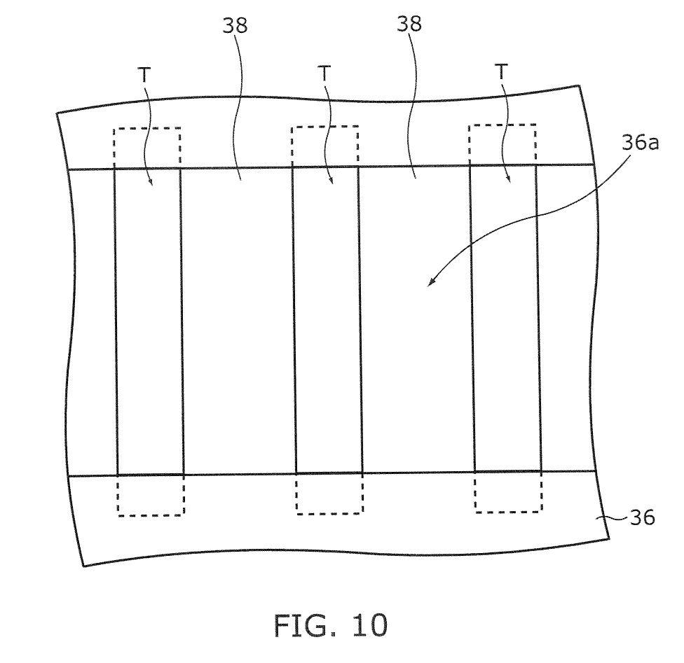

Next, an etching mask (not shown) is formed on the surface of the N⁻-type silicon layer 3. For example, after a thermal oxide film is formed on the surface of the N⁻-type silicon layer 3, openings are selectively formed in the oxide film. Then the N⁻-type silicon layer 3 is anisotropically etched through the openings. Thus, as shown in FIG. 8, trenches T are formed, extending from the surface of the N⁻-type silicon layer 3 to the substrate 2. The trench T is substantially perpendicular to the major surface of the substrate 2. FIG. 9 is a plan view of the N⁻-type silicon layer 3 with the trenches T formed therein as viewed from the upper surface side (from the opening side of the trench T).

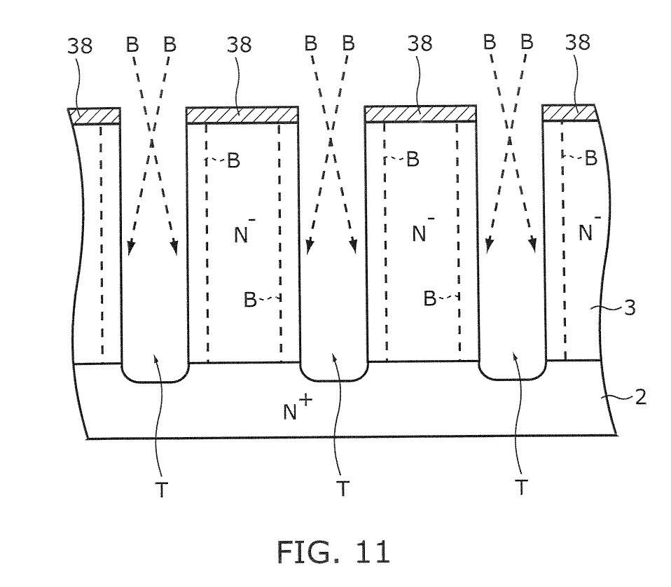

Next, on the surface of the N⁻-type silicon layer 3 is formed a stopper film 38 (see FIG. 11) for preventing ion implantation into this surface. Then, as shown in FIG. 10, a stencil mask 36 for ion implantation is overlaid. The stencil mask 36 has an opening 36a extending along the aligned direction of the trenches T. The width of the opening 36a is shorter than the longitudinal length of the opening of the trench T. Therefore both ends of the opening of the trench T are covered with the stencil mask 36. For example, the portion extending to about 30 micrometers inside from the ends of the trench T is covered with the stencil mask 36, and the other portion of the opening of the trench T is left open.

In the state where both ends of the trench T are thus covered with the stencil mask 36, P-type impurities such as boron (B) are injected into the sidewall of the trench T in an oblique direction (e.g., at an angle of 3 to 7° with respect to the depth direction) as shown in FIG. 11. After one of the sidewalls of the trench T is subjected to ion implantation, the wafer is rotated 180 degrees, and the other sidewall is also subjected to ion implantation. At this time, because both ends of the trench T are covered with the stencil mask 36, boron is not injected into the trench sidewall in the covered portion.

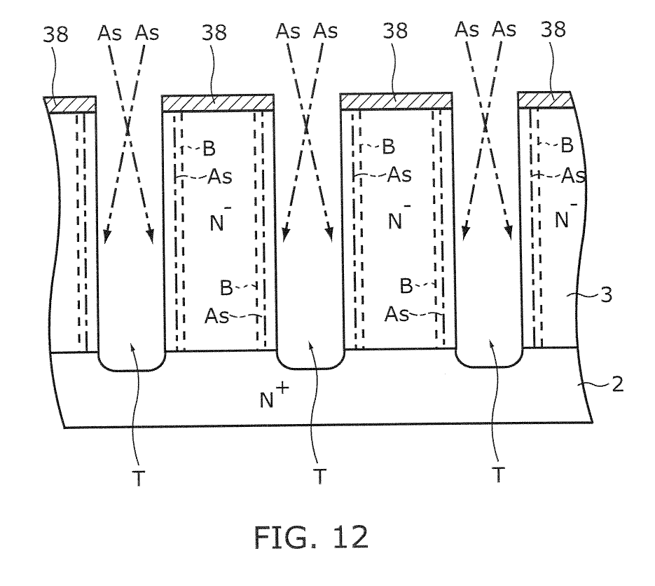

Next, likewise, in the state where both ends of the trench T are covered with the stencil mask 36, N-type impurities such as arsenic (As) are injected into the sidewall of the trench T in an oblique direction (e.g., at an angle of 3 to 70 with respect to the depth direction) as shown in FIG. 12. After one of the sidewalls of the trench T is subjected to ion implantation, the wafer is rotated 180 degrees and the other sidewall is also subjected to ion implantation. At this time again, because both ends of the trench T are covered with the stencil mask 36, arsenic is not injected into the trench sidewall in the covered portion.

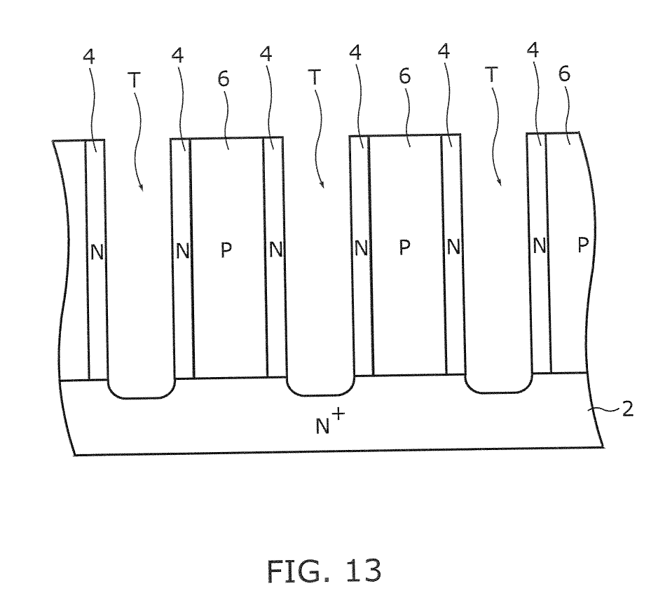

After the ion implantation step described above, heat treatment is conducted to diffuse and activate arsenic and boron injected into the N⁻-type silicon layer 3. FIG. 13 shows the state after this heat treatment step. Activated arsenic and boron act as donors and acceptors, respectively, to form an N-type pillar region 4 and a P-type pillar region 6 in the N⁻-type silicon layer 3. Here, because the diffusion coefficient of boron is larger than the diffusion coefficient of arsenic, boron diffuses into the interior of the N⁻-type silicon layer 3 more distant from the sidewall of the trench T. Therefore, because the arsenic concentration becomes higher than the boron concentration in the vicinity of the sidewall of the trench T, an N-type pillar region 4 is formed on the side closer to the sidewall of the trench T. A P-type pillar region 6 is formed in the deeper portion as viewed from the sidewall of the trench T.

Here, as described above, because N-type impurities and P-type impurities are not injected into the sidewall in the vicinity of both ends of the trench T, the N-type pillar region 4 and the P-type pillar region 6 are not formed in the vicinity of both ends of the trench T as shown in the planar structure of FIG. 1. That is, the vicinity of both ends of the trench T is left to be of N⁻-type.

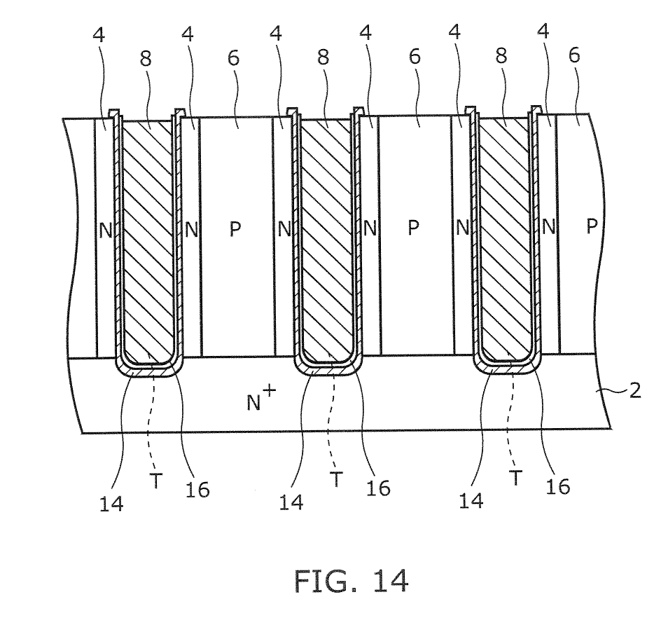

After the foregoing heat treatment step, a dielectric 8 is buried inside the trench T as shown in FIG. 14. Specifically, for example, a silicon oxide film 14 is formed by thermal oxidation on the sidewall and the bottom surface of the trench T, and a silicon nitride film 16 is formed on the surface of the silicon oxide film 14. Then a dielectric 8 made of silica is deposited inside the trench T by vapor deposition, for example. Alternatively, heat treatment may be conducted after burying a dielectric 8 inside the trench T, to diffuse and activate arsenic and boron injected into the N⁻-type silicon layer 3.

Next, as shown in FIG. 2, a control electrode 30 is formed via insulating films 24, 26 and used as a mask for ion implantation into the surface of the P-type pillar region 6, thereby forming a P-type base region 18 in a self-aligned manner. Furthermore, a P⁺-type base contact region 19 and a source region 22 are selectively formed on the surface of the P-type base region 18.

Next, an interlayer insulating film 28 is formed so as to cover the control electrode 30. A contact hole is formed for source contact in the interlayer insulating film 28. Part of the base contact region 19 and the source region 22 is exposed through the contact hole. A first main electrode 32 is formed on the interlayer insulating film 28 so as to fill the contact hole. A second main electrode 34 is formed on the surface opposite to the major surface of the substrate 2. Thus a semiconductor device 11 shown in FIG. 2 is obtained.

Second Embodiment

Next, a second embodiment of the invention is described Elements similar to those in the first embodiment described above are marked with the same reference numerals and not described in detail.

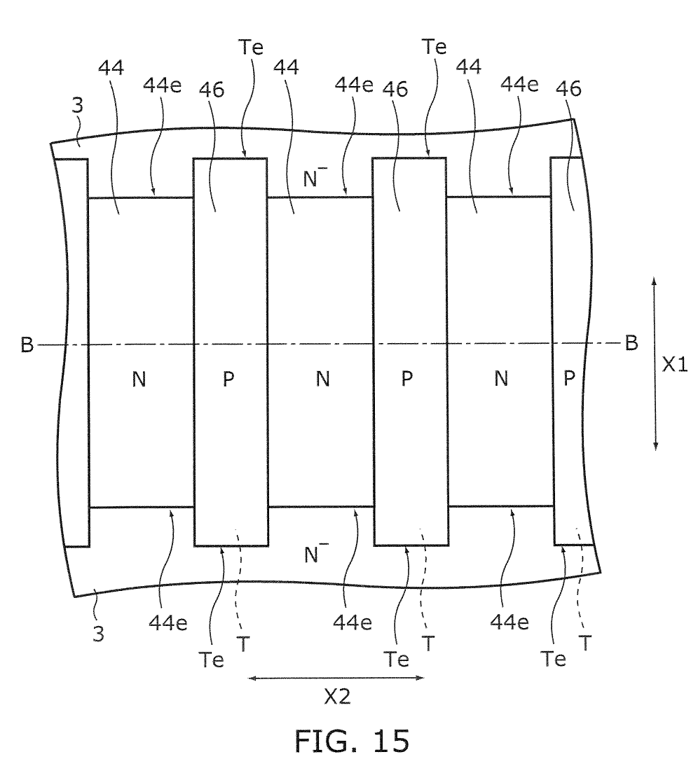

FIG. 15 is a schematic view illustrating the planar structure of the cell of a semiconductor device according to the second embodiment of the invention.

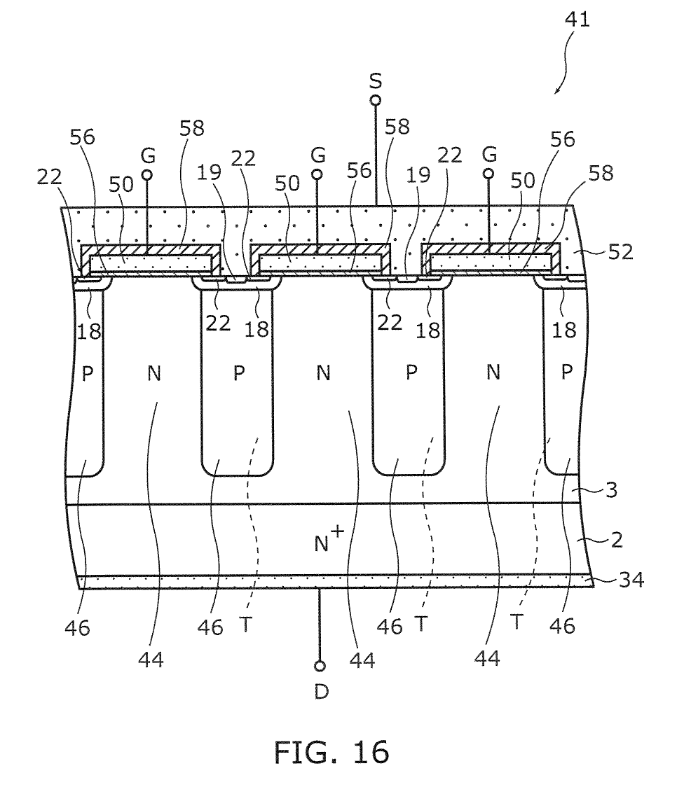

FIG. 16 is a schematic view illustrating the cross-sectional structure of the cell of the semiconductor device along the line B-B in FIG. 15.

Like the first embodiment, the semiconductor device 41 according to this embodiment has N-type pillar regions 44 and P-type pillar regions 46 formed on a silicon substrate 2 in parallel. The difference from the first embodiment is that the inside of the trench T is filled with the P-type pillar region 46 by epitaxial growth.

As shown in the cross-sectional structure of FIG. 16, the N-type pillar region 44 and the P-type pillar region 46 (trench T) extend substantially perpendicular to the major surface of the substrate 2. The N-type pillar region 44 and the P-type pillar region 46 are adjacent to each other to form a PN junction. As described above with reference to the first embodiment, the trench T may be formed deeply to reach the N⁺-type silicon substrate (first semiconductor layer) 2.

FIG. 15 shows the planar structure of the N-type pillar region 44 and the P-type pillar region 46 (trench T). The N-type pillar region 44 and the P-type pillar region 46 (trench T) extend along a first direction X1. The first direction X1 is a direction substantially perpendicular to the depth direction of the trench T and corresponds to the direction going through the page in the cross section of FIG. 16.

The length of the N-type pillar region 44 along the first direction X1 is shorter than the length of the P-type pillar region 46 (trench T) along the first direction X1. Both ends 44e of the N-type pillar region 44 in the first direction X1 are located more inside than both ends Te of the P-type pillar region 46 (trench T) in the first direction X1. For example, the P-type pillar region 46 (trench T) has a length of 2.5 to 4 millimeters along the first direction X1. Both ends 44e of the N-type pillar region 44 in the first direction X1, respectively, are located more inside than both ends Te of the P-type pillar region 46 (trench T) by about 10 to 50 micrometers, for example. Conversely, both ends Te of the P-type pillar region 46 (trench T) protrude from both ends 44e of the N-type pillar region 44 by about 10 to 50 micrometers.

An active region (base region 18, source region 22) described below is formed on the P-type pillar region 46. The ends of the active region in the first direction X1 do not extend to both ends Te of the P-type pillar region 46 (trench T). Preferably, the ends of the active region in the first direction X1 slightly extend out from the ends 44e of the N-type pillar region 44.

Referring again to FIG. 16, a base region 18 of P-type silicon is provided on a portion of the P-type pillar region 46 except both ends thereof, which portion is to serve as an active region. Furthermore, a base contact region 19 of P⁺-type silicon having a higher impurity concentration than the base region 18 is provided on the surface of the base region 18. Moreover, a semiconductor region (source region) 22 of N⁺-type silicon is provided on the surface of the base region 18 so as to sandwich the base contact region 19. The base region 18 is adjacent to the N-type pillar region 44 to form a PN junction.

An insulating film 56 is provided on the surface of the portion extending from the N-type pillar region 44 via the base region 18 to the source region 22. This insulating film 56 is gate insulating film. A control electrode (gate electrode) 50 is provided on the insulating film 56. The periphery and the upper surface of the control electrode 50 are covered with an interlayer insulating film 58. A first main electrode (source electrode) 52 is provided on the portion of the source region 22 not covered with the interlayer insulating film 58, on the base contact region 19, and on the interlayer insulating film 58. The source region 22 is connected to the first main electrode 52. The base region 18 is connected to the first main electrode 32 via the base contact region 19. A second main electrode (drain electrode) 34 is provided on the surface opposite to the major surface of the substrate 2.

In the semiconductor device 41 configured as above, a prescribed control voltage is applied to the control electrode 50. Then an N-channel is formed in the vicinity of the surface of the P-type base region 18 immediately below the control electrode 50, and the N⁺-type source region 22 becomes conductive to the N-type pillar region 44. As a result, a main current path is formed between the first main electrode 52 and the second main electrode 34 via the N⁺-type source region 22, the N-type pillar region 44, and the N⁺-type substrate 2. Thus the path between these electrodes 52, 34 is turned on.

The device withstand voltage can be maintained by the depletion layer laterally extending from the PN junction between the N-type pillar region 44 and the P-type base region 18 and from the PN junction between the N-type pillar region 44 and the P-type pillar region 46.

In the semiconductor device 41 according to this embodiment, as described above with reference to FIG. 15, the N-type pillar region 44 is not formed in the vicinity of the ends of the trench T (about 10 to 50 micrometers inside from the end Te of the trench T).

As described above, this embodiment also has a structure such that the vicinity of the bottom near the trench end, where crystal defects are likely to concentrate, is not at all used as a main current path of the device. Therefore, even if any crystal defects occur in the vicinity of the trench end, they do not affect the product quality. This results in products with high yield and good quality.

Next, an example method of manufacturing a semiconductor device according to this embodiment is described.

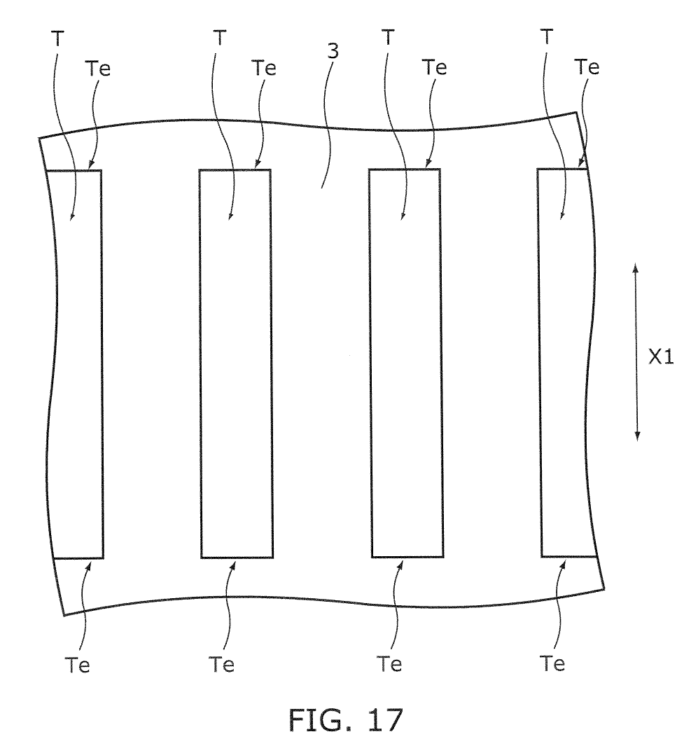

FIGS. 17 to 23 are process cross sections illustrating the relevant part of a process of manufacturing a semiconductor device according to this embodiment.

Like the first embodiment, on a major surface of an N⁺-type silicon substrate (first semiconductor layer) 2 having a high impurity concentration, an N⁻-type silicon layer (second semiconductor layer) 3 having a low impurity concentration is epitaxially grown. Then trenches T are formed in the N⁻-type silicon layer 3. FIG. 17 is a plan view of the N⁻-type silicon layer 3 with the trenches T formed therein as viewed from the upper surface side (from the opening side of the trench T).

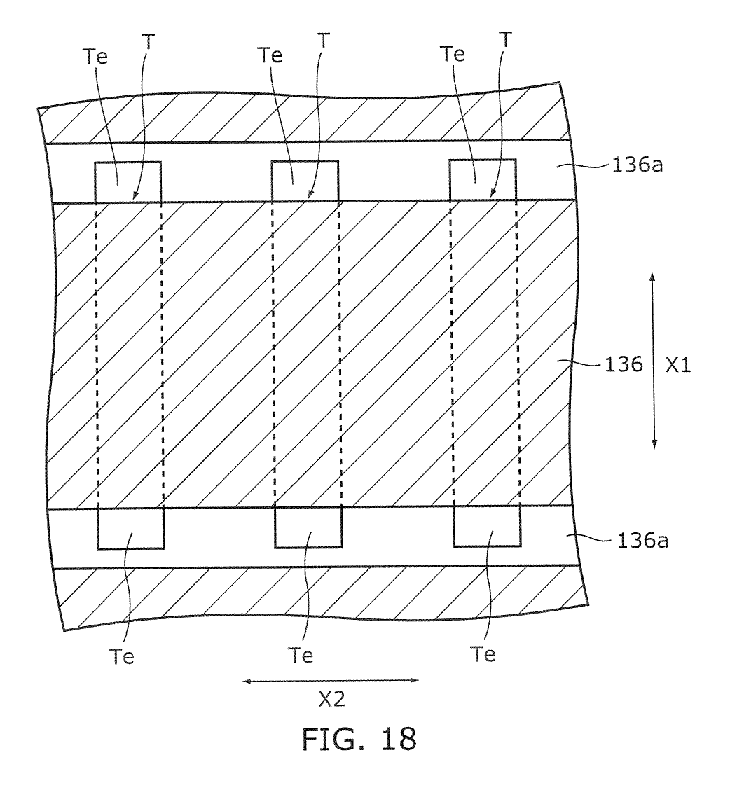

Next, on the surface of the N⁻-type silicon layer 3 is formed a stopper film for preventing ion implantation into this surface. Then, as shown in FIG. 18, a stencil mask 136 is overlaid. The stencil mask 136 has an opening 136a extending along the second direction X2. Both ends Te of the trench T in the first direction X1 are open through the opening 136a. For example, the portion extending to about 10 to 50 micrometers from the edge of the trench T is open through the opening 136a.

In the state, oxygen or nitrogen is injected into the bottom of the sidewall of the both ends Te of the trench T in an oblique direction (e.g., at an angle of 3 to 7° with respect to the depth direction) by ion-implantation technique. For example, dose amount in this ion implantation is 1×10¹³ to 1×10¹⁵/cm². Thus, the bottom of the sidewall of the both ends Te of the trench T is electrically inactivated. Leakage current easily occurs in the bottom of the sidewall of the both ends of the trench while operating. However, the leakage current can be suppressed because the bottom of the sidewall of the both ends Te of the trench T is electrically inactivated in this embodiment.

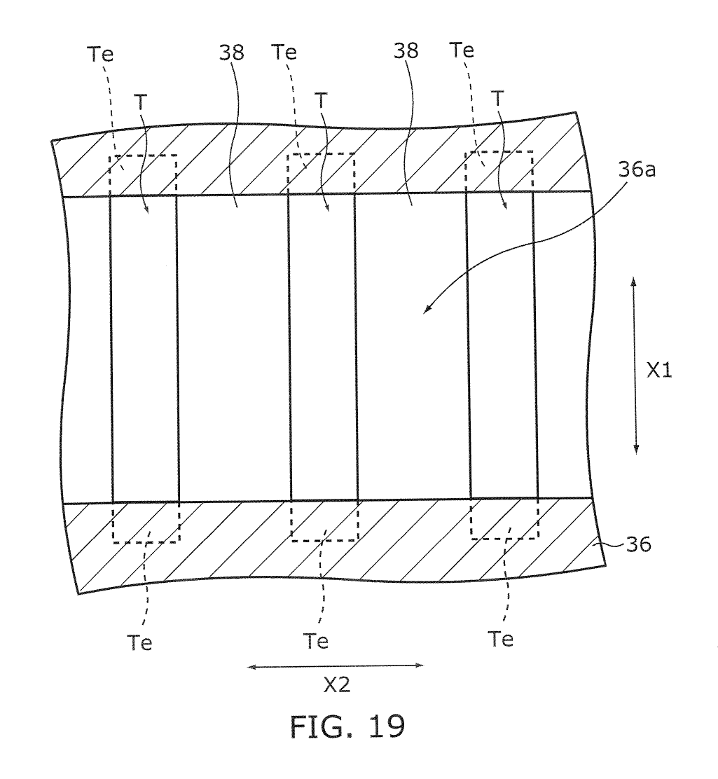

Next, on the surface of the N⁻-type silicon layer 3 is formed a stopper film 38 for preventing ion implantation into this surface. Then, as shown in FIG. 19, a stencil mask 36 for ion implantation is overlaid. As described above with reference to FIG. 10, the stencil mask 36 has an opening 36a extending along the aligned direction of the trenches T. The width of the opening 36a is shorter than the longitudinal length of the opening of the trench T. Therefore both ends of the opening of the trench T are covered with the stencil mask 36. For example, the portion extending to about 30 micrometers inside from the ends of the trench T is covered with the stencil mask 36, and the other portion of the opening of the trench T is left open.

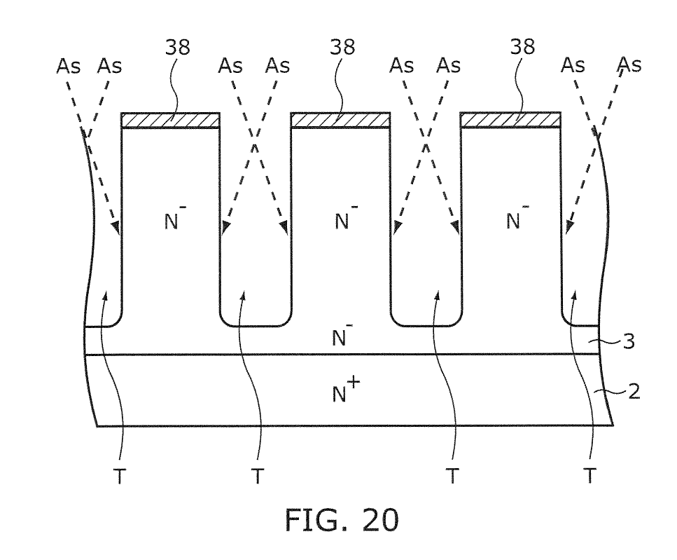

In the state where both ends of the trench T are thus covered with the stencil mask 36, N-type impurities such as arsenic (As) are injected into the sidewall of the trench T in an oblique direction (e.g., at an angle of 3 to 7° with respect to the depth direction) as shown in FIG. 20. After one of the sidewalls of the trench T is subjected to ion implantation, the wafer is rotated 180 degrees, and the other sidewall is also subjected to ion implantation. At this time, because both ends of the trench T are covered with the stencil mask 36, arsenic is not injected into the trench sidewall in the covered portion. Process sequence of the ion implantation of oxygen or nitrogen and the ion implantation of N-type impurities can be reversed.

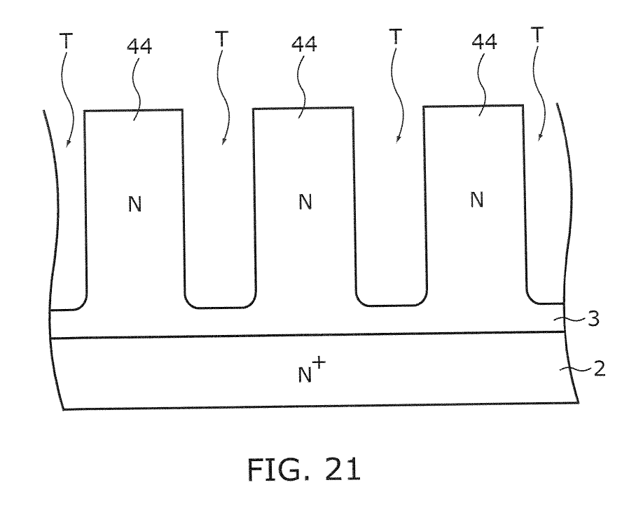

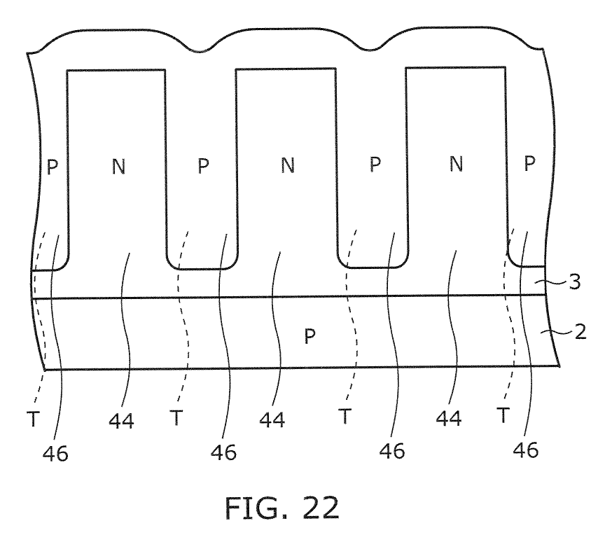

After the ion implantation step described above, heat treatment is conducted to diffuse and activate arsenic injected into the N⁻-type silicon layer 3. FIG. 21 shows the state after this heat treatment step. Activated arsenic acts as donors to form an N-type pillar region 44 in the N⁻-type silicon layer 3.

Next, as shown in FIG. 21, a P-type pillar region 46 is epitaxially grown by chemical vapor deposition using silane gas, disilane gas, dichlorosilane gas, trichlorosilane gas, or mixed gas of above each gas and hydrochloric acid gas for example, so as to fill the inside of the trench T.

Next, for example, it is annealed in the presence of nitrogen gas at 1150 to 1200 degrees centigrade for nine hours. The annealing ambient is not limited nitrogen gas, but can be argon gas or vacuum.

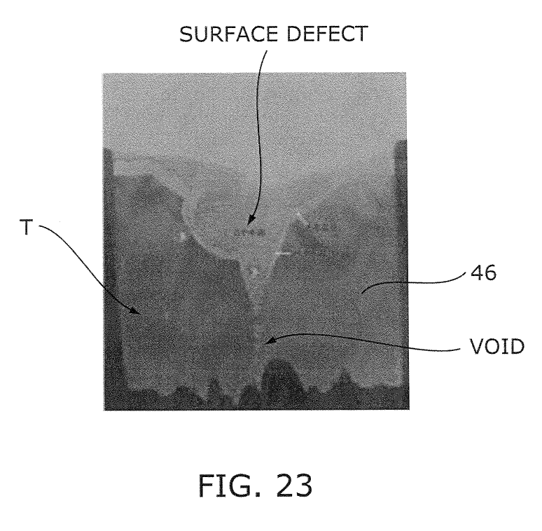

FIG. 23 is an electron micrograph of the cross section in relation to FIG. 22 after the annealing.

Crystal defects are observed inside of the trench T before the annealing. But crystal defects are not observed after the annealing. Only microscopic void are observed after the annealing. However, crystal defects in the vicinity of the surface are observed after the annealing.

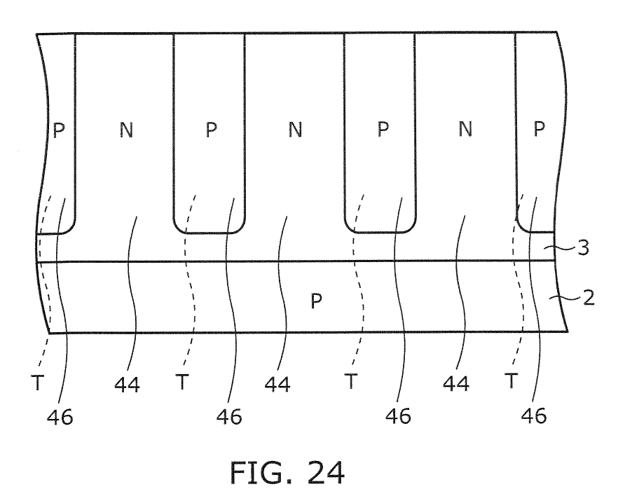

After the above annealing, the P-type pillar region 46 grown above than an open end of the trench T is polished by CMP (chemical mechanical polishing) process. Then the P-type pillar region 46 is planarized as shown in FIG. 24. Thus, surface defects in the P-type pillar region 46 are removed.

Next, as shown in FIG. 16, a control electrode 50 is formed via an insulating film 56 and used as a mask for ion implantation into the surface of the P-type pillar region 46, thereby forming a P-type base region 18 in a self-aligned manner. The P-type base region 18 does not extend to the ends Te of the trench T in the first direction X1 (see FIG. 15). That is, both ends of the P-type base region 18 in the first direction X1 are located more inside than both ends Te of the trench T in the first direction X1. Next, a P⁺-type base contact region 19 and a source region 22 are selectively formed on the surface of the P-type base region 18.

Next, an interlayer insulating film 58 is formed so as to cover the control electrode 50. A contact hole is formed for source contact in the interlayer insulating film 58. Part of the base contact region 19 and the source region 22 is exposed through the contact hole. A first main electrode 52 is formed on the interlayer insulating film 58 so as to fill the contact hole. A second main electrode 34 is formed on the surface opposite to the major surface of the substrate 2. Thus a semiconductor device 41 shown in FIG. 16 is obtained. No active region (base region 18, source region 22) is formed in the vicinity of the ends of the trench T.

Third Embodiment

The invention can be applied not only to MOSFETS, but also to other semiconductor devices having the so-called super junction structure such as IGBTs (Insulated Gate Bipolar Transistors), which are also encompassed within the scope of the invention.

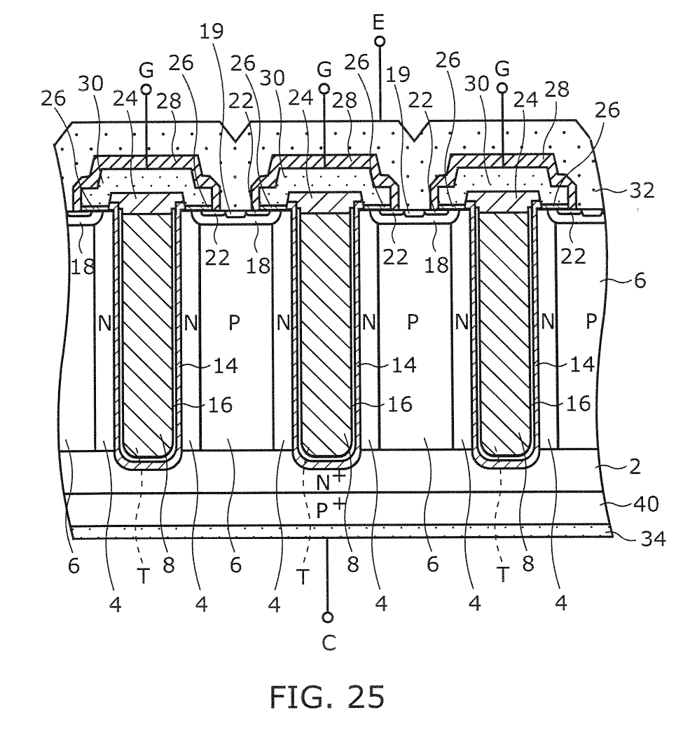

FIG. 25 is a schematic cross section showing the structure of an IGBT according to the embodiment of the invention.

The vertical IGBT illustrated in this figure has a P⁺-collector layer 40 formed on the backside of the N⁺-type layer 2. An emitter electrode 32 is provided as a first main electrode, and a collector electrode 34 is provided as a second main electrode. Although the nomenclature of individual elements and part of the structure are different from the MOSFET described above with reference to FIG. 2, the configuration in the vicinity of the super junction structure is the same. Note that the structure described above with reference to FIG. 16 can be similarly altered to the IGBT, which is also encompassed within the scope of the invention.

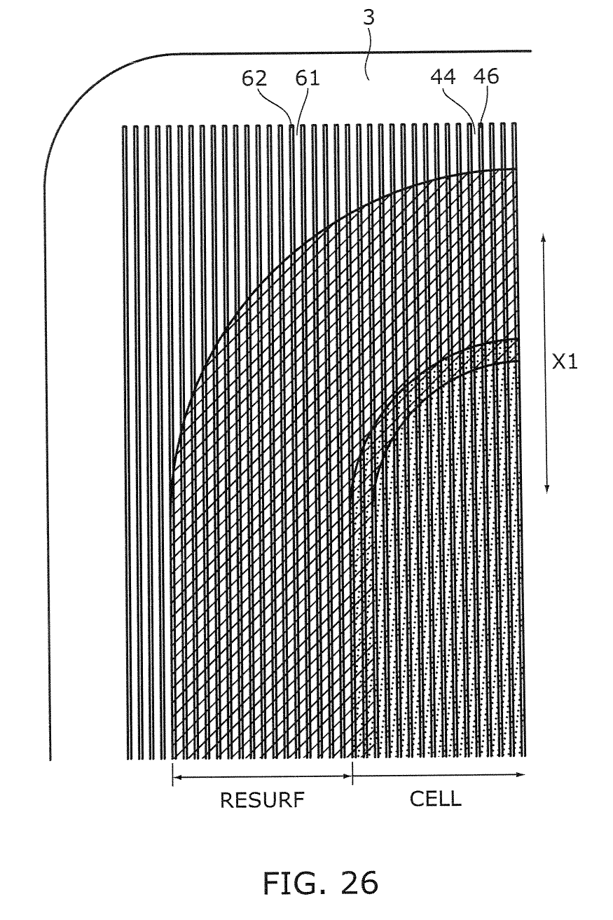

FIG. 26 is a schematic view illustrating the planar structure of the termination of the semiconductor device according to the above second embodiment of the invention,

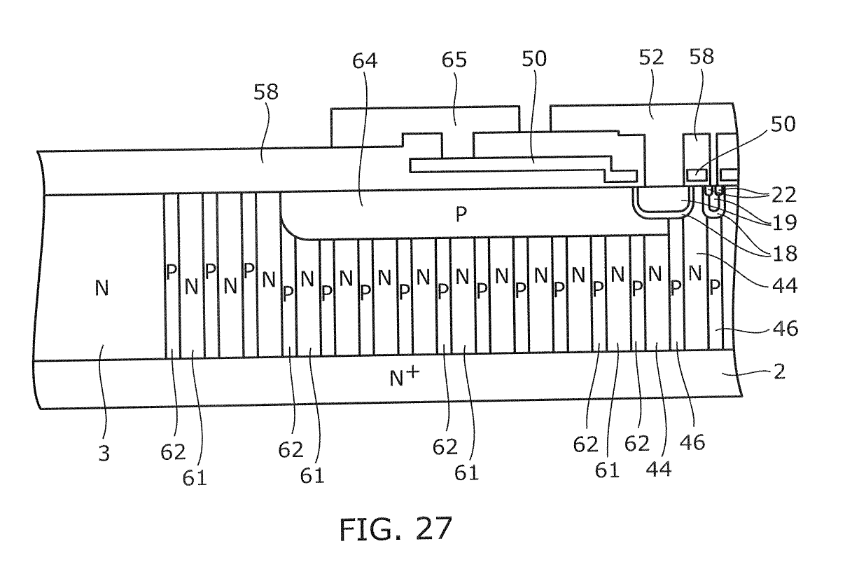

FIG. 27 is a schematic view illustrating the cross-sectional structure of the termination of the semiconductor device according to the second embodiment.

Third semiconductor pillar regions 61 of the first conductivity type (N-type pillar region) and fourth pillar regions 62 of the second conductivity type (P-type pillar region) are provided in parallel on the major surface of the semiconductor layer 2 in a termination. The termination is outside of the base region 18. The N-type pillar region 61 is adjacent to the P-type pillar region 62 to form a PN junction.

A RESURF (reduced surface field) region 64 of the second conductivity type (P-type) is provided in the surface layer of the termination. The RESURF region 64 is provided on the N-type pillar region 61 and the P-type pillar region 62. A field plate electrode 65 is provided on the surface of the termination via an insulating layer 58. The field plate electrode 65 is connected to the control electrode 50. The field plate electrode 65 can be connected to the source electrode 52.

The alignment pitch of the N-type pillar region 61 and the P-type pillar region 62 in the termination is shorter than that of the N-type pillar region 44 and the P-type pillar region 46 in the cell. Alternatively, the impurity concentration of the portion aligned the N-type pillar region 61 and the P-type pillar region 62 in the termination is lower than that of the portion aligned the N-type pillar region 44 and the P-type pillar region 46 in the cell. Thus, the depletion layer easily extends in the termination where the withstand voltage can be hard to maintain than the cell. Accordingly, the reduction of the withstand voltage in the termination can be suppressed.

Embodiments of the invention have been described with reference to specific examples. However, the invention is not limited thereto, but can be variously modified on the basis of the spirit of the invention.

Material of the semiconductor is not limited to silicon, but may be other materials such as silicon carbide (SiC), gallium nitride (GaN), gallium arsenide (GaAs), aluminum nitride (AlN), boron nitride (BN), indium nitride (InN), germanium (Ge), silicon germanium (SiGe), for example.

In the structures described above, the conductivity type of each element can be reversed.

Furthermore, in the first embodiment, the combination of the two types of impurities, that is, P-type and N-type impurities, injected into the sidewall of the trench T is not limited to the above-described one. For example, in the case of N-channel devices, any combination can be used as long as the diffusion coefficient of P-type impurities is larger than the diffusion coefficient of N-type impurities.

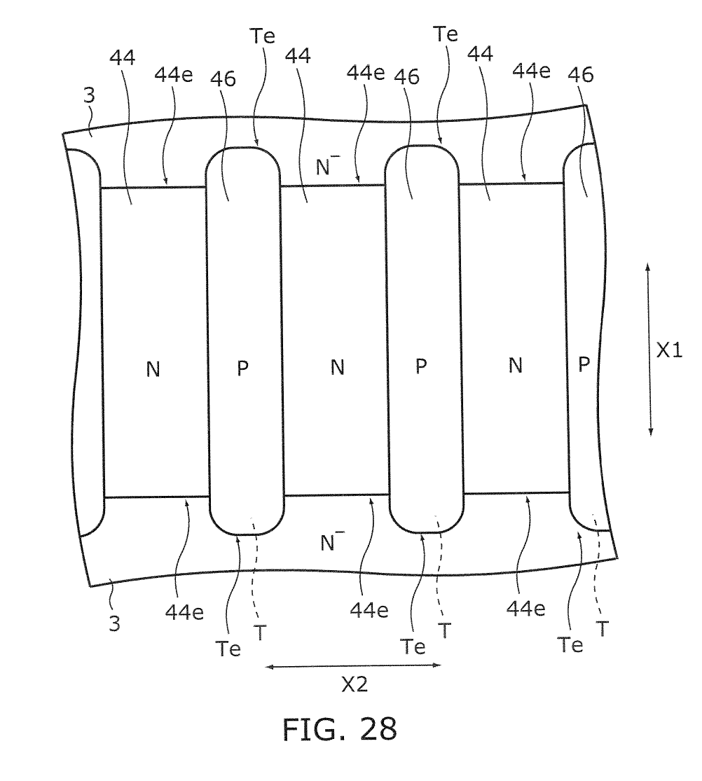

As shown in FIG. 28, the end Te of the trench T can be shaped roundly.

1. A semiconductor device comprising:
a semiconductor layer of a first conductivity type;
a first semiconductor pillar region of the first conductivity type provided on a major surface of the semiconductor layer;
a second semiconductor pillar region of a second conductivity type provided on the major surface of the semiconductor layer, the second semiconductor pillar region being adjacent to the first semiconductor pillar region; and
a dielectric filled inside a trench, the trench being provided adjacent to the first semiconductor pillar region and away from the second semiconductor pillar region,
wherein the first semiconductor pillar region, the second semiconductor pillar region, and the trench are extending along a first direction, the first direction is substantially perpendicular to the depth direction of the trench, and at least both ends of the first semiconductor pillar region in the first direction are provided more inside than both ends of the trench in the first direction.

2. The semiconductor device according to claim 1, wherein the dielectric includes at least one of silica, nitride and oxide.

3. The semiconductor device according to claim 1, further comprising:
a semiconductor base region of the second conductivity type provided on the second semiconductor pillar region;
a semiconductor region of the first conductivity type selectively provided in the surface portion of the semiconductor base region;
an insulating film provided on the semiconductor base region interposed between the semiconductor region and the first semiconductor pillar region;
a control electrode provided on the insulating film;
a first main electrode provided on the semiconductor region; and
a second main electrode provided on an opposite side of the major surface of the semiconductor layer.

4. The semiconductor device according to claim 1, wherein both ends of the first semiconductor pillar region in the first direction and both ends of the second semiconductor pillar region in the first direction are provided more inside than both ends of the trench in the first direction.

5. The semiconductor device according to claim 1, wherein the first semiconductor pillar region is made of N-type semiconductor and the second semiconductor pillar region is made of P-type semiconductor.

6. A semiconductor device comprising:
a semiconductor layer of a first conductivity type;
a first semiconductor pillar region of the first conductivity type provided on a major surface of the semiconductor layer; and
a second semiconductor pillar region of a second conductivity type filled inside a trench, the trench being provided adjacent to the first semiconductor pillar region,
wherein the first semiconductor pillar region and the trench are extending along a first direction, the first direction is substantially perpendicular to the depth direction of the trench, and both ends of the first semiconductor pillar region in the first direction are provided more inside than both ends of the trench in the first direction.

7. The semiconductor device according to claim 6, further comprising:
a semiconductor base region of the second conductivity type provided on the second semiconductor pillar region;
a semiconductor region of the first conductivity type selectively provided in the surface portion of the semiconductor base region;
an insulating film provided on the semiconductor base region interposed between the semiconductor region and the first semiconductor pillar region;
a control electrode provided on the insulating film;
a first main electrode provided on the semiconductor region; and
a second main electrode provided on an opposite side of the major surface of the semiconductor layer.

8. The semiconductor device according to claim 7, wherein both ends of the semiconductor base region in the first direction and both ends of the semiconductor region in the first direction are provided more inside than both ends of the trench in the first direction.

9. The semiconductor device according to claim 7, further comprising:
a third semiconductor pillar region of the first conductivity type provided on the major surface of the semiconductor layer in a termination, the termination being outside of the semiconductor base region; and
a fourth semiconductor pillar region of the second conductivity type provided on the major surface of the semiconductor layer, the fourth semiconductor pillar region being adjacent to the third semiconductor pillar region.

10. The semiconductor device according to claim 9, wherein an alignment pitch of the third semiconductor pillar region and the forth semiconductor pillar region is shorter than an alignment pitch of the first semiconductor pillar region and the second semiconductor pillar region.

11. The semiconductor device according to claim 9, wherein an impurity concentration of a portion aligned the third semiconductor pillar region and the forth semiconductor pillar region is lower than that of a portion aligned the first semiconductor pillar region and the second semiconductor pillar region.

12. The semiconductor device according to claim 9, further comprising a RESURF region of the second conductivity type provided on a portion aligned the third semiconductor pillar region and the forth semiconductor pillar region.

13. The semiconductor device according to claim 6, wherein at least one of oxygen or nitrogen is injected into both ends of the trench in the first direction.

14. A method of manufacturing a semiconductor device, comprising:
forming a trench in a second semiconductor layer formed on a major surface of a first semiconductor layer of a first conductivity type;
injecting impurities of the first conductivity type into a sidewall of the trench while both ends of the trench are covered with a mask;
forming a first semiconductor pillar region of the first conductivity type adjacent to the trench by diffusing the impurities of the first conductivity type; and
forming a second semiconductor pillar region of the second conductivity type adjacent to the first semiconductor pillar region.

15. The method of manufacturing a semiconductor device according to claim 14, further comprising burying a dielectric inside the trench.

16. The method of manufacturing a semiconductor device according to claim 15, wherein the dielectric includes at least one of silica, nitride and oxide.

17. The method of manufacturing a semiconductor device according to claim 14, wherein the second semiconductor pillar region is epitaxially grown inside the trench.

18. The method of manufacturing a semiconductor device according to claim 17, further comprising annealing the second semiconductor pillar region after the epitaxial growth of the second semiconductor pillar region.

19. The method of manufacturing a semiconductor device according to claim 18, wherein the second semiconductor pillar region is annealed in an atmosphere including nitrogen gas.

20. The method of manufacturing a semiconductor device according to claim 17, further comprising removing the second semiconductor pillar region grown above than an open end of the trench by polishing.
